(19) United States
(12) Patent Application Publication
(10) Pub. No.: US 2022/0207713 A1
(43) Pub. Date: Jun. 30, 2022

(54) METHOD AND SYSTEM FOR MANUFACTURING INTEGRATED CIRCUIT

(71) Applicant: KLA Corporation, Milpitas, CA (US)

(72) Inventors: Haifeng Pu, Shanghai (CN); Ningqi Zhu, Shanghai (CN); Shengyuan Zhong, Shanghai (CN)

(21) Appl. No.: 17/168,769

(22) Filed: Feb. 5, 2021

(30) Foreign Application Priority Data
Dec. 30, 2020 (CN) 202011612527.1

(51) Int. Cl. G06T 7/00

(52) U.S. Cl. CPC G06T 7/0006; G06T 2207/30208; G06T 2207/30148

(57) ABSTRACT

The method for manufacturing an integrated circuit includes: calculating a loss value according to first measurement data and first compensation data associated with a first group of marks on a wafer and second measurement data and second compensation data associated with a second group of marks on the wafer; and adjusting a first parameter set associated with the first compensation data and the second compensation data such that a difference between the loss value and a target loss value to be less than a loss threshold.

### CROSS-REFERENCE TO RELATED APPLICATIONS

This application claims priority to Chinese Patent Application No. 202011612527.1 filed Dec. 30, 2020, the disclosure of which is hereby incorporated by reference.

### FIELD OF THE INVENTION

The present invention generally relates to the field of semiconductor technologies, and more specifically, to a method and system for manufacturing an integrated circuit.

### BACKGROUND OF THE INVENTION

Photolithography is a key process in the field of integrated circuit manufacturing. The process quality of photolithography directly affects indicators such as the yield, reliability, chip performance, and service life of integrated circuits. Improvements in the process quality of photolithography are closely correlated to the stability of these indicators.

One type of photolithography is referred to as a photolithographic method. In the method, a photomask is illuminated by light, such as ultraviolet light, to transfer a pattern on the photomask to a photoresist on a wafer by exposure. The photoresist includes one or more components that undergo chemical transformation during exposure to ultraviolet radiation. Therefore, property changes that occur in the photoresist allow selective removal of an exposed part or an unexposed part of the photoresist. In this way, through photolithography, the pattern from the photomask may be transferred to the photoresist, and the photoresist is then selectively removed to expose the pattern. In addition, the foregoing operations may be repeated to implement photolithography that superimposes a plurality of pattern layers.

With the continuous innovation of semiconductor process technologies, how to control overlay offsets between a plurality of pattern layers already becomes a key factor for the yield of integrated circuits. How to reduce overlay offsets already becomes one of the major challenges in the semiconductor industry. In another aspect, due to the limitation of photomask sizes, a stitching technology is widely adopted in the manufacturing of charge-coupled devices (CCD) and complementary metal-oxide-semiconductor (CMOS) image sensors (CIS). How to control stitching offsets is another challenge.

An anamorphic lens is introduced into a high-numerical aperture extreme ultraviolet (EUV) photolithography technology, to provide a pattern layer with a higher resolution. In this technology, a pattern on a photomask needs to be stretched in a single direction for deformation (for example, in an X direction), and the deformed pattern on the photomask requires repeated exposure and a stitching technology is used to form a pattern layer on a wafer. The control of stitching offsets is also indispensable in the high-numerical aperture EUV photolithography technology. The calibration of overlay offsets and stitching offsets play an important role in photolithography.

### SUMMARY OF THE INVENTION

One of the objectives of the embodiments of the present invention is to provide a method for manufacturing an integrated circuit, so that stitching offsets and overlay offsets are considered while offsets are calibrated, thereby effectively reducing stitching offsets and overlay offsets in the process of manufacturing an integrated circuit.

An embodiment of the present invention provides a method for manufacturing an integrated circuit, including: calculating a loss value according to first measurement data and first compensation data associated with a first group of marks on a wafer and second measurement data and second compensation data associated with a second group of marks on the wafer; and adjusting a first parameter set associated with the first compensation data and the second compensation data, to enable a difference between the loss value and a target loss value to be less than a loss threshold. Another embodiment of the present invention provides a method for manufacturing an integrated circuit, including: calculating a loss value according to the following equation: L²=αΣᵢ₌₁ⁿ(OVLᵢ−OVL_{M}_{ᵢ})²+βΣⱼ₌₁^{m} (stitchⱼ−stitch_{M}_{ⱼ})². L² is the loss value; OVLᵢ is first compensation data associated with a first group of marks on a wafer; OVL_{M}_{ᵢ} is first measurement data associated with the first group of marks; Stitchⱼ is second compensation data associated with a second group of marks on the wafer; Stitch_{M}_{ⱼ} is second measurement data associated with the second group of marks; and a is a first weight value; and β is a second weight value.

Still another embodiment of the present invention further provides a system for manufacturing an integrated circuit, including: a processor, a nonvolatile computer-readable medium storing computer executable instructions, and a handler. The nonvolatile computer-readable medium storing computer executable instructions is coupled to the processor. The handler is configured to support a wafer. The processor executes the computer executable instructions to implement the method for manufacturing an integrated circuit according to the foregoing embodiments on the wafer.

### BRIEF DESCRIPTION OF THE DRAWINGS

FIG. 1 is a schematic diagram of a wafer according to an embodiment of the present invention.

FIG. 2(a) is a schematic diagram of a region on a wafer according to an embodiment of the present invention.

FIG. 2(b) is a schematic diagram of a region on a wafer according to another embodiment of the present invention.

FIG. 3(a) is a schematic diagram of measurement data according to an embodiment of the present invention.

FIG. 3(b) is a schematic diagram of compensation data according to an embodiment of the present invention.

FIG. 4 is a flowchart of a method for manufacturing an integrated circuit according to an embodiment of the present invention.

FIG. 5(a) is a vector diagram of overlay offsets after the method shown in FIG. 4 is performed.

FIG. 5(b) is a vector diagram of stitching offsets obtained after the method shown in FIG. 4 is performed.

FIG. 6 is a flowchart of a method for manufacturing an integrated circuit according to a comparative embodiment of the present invention.

FIG. 7 is a flowchart of a method for manufacturing an integrated circuit according to a comparative embodiment of the present invention.

FIG. 8(a) is a vector diagram of overlay offsets after the method shown in FIG. 6 is performed.

FIG. 8(b) is a vector diagram of stitching offsets obtained after the method shown in FIG. 6 is performed.

FIG. 9 is an exemplary system in accordance with the present disclosure.

### DETAILED DESCRIPTION

To better understand the spirit of the present invention, the present invention is further described below with reference to some preferred embodiments of the present invention.

Hereinafter, various embodiments of the present invention will be described in detail. Although specific implementations are discussed, it should be understood that these implementations are used for description. It is apparent to a person skilled in the art that other members and configurations may be used without departing from the spirit and protection scope of the present invention.

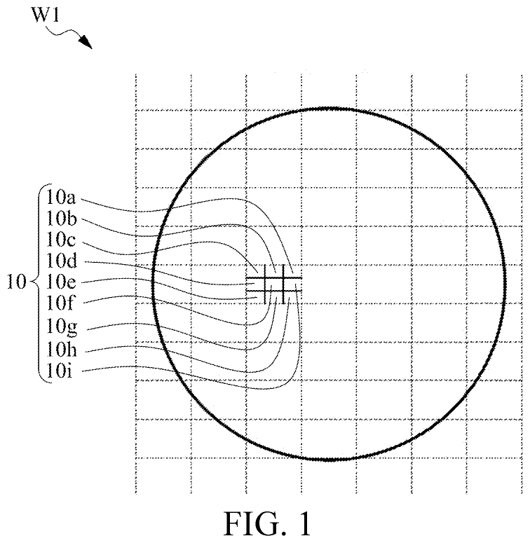

FIG. 1 is a schematic diagram of a wafer according to an embodiment of the present invention.

FIG. 1 is a schematic diagram of a wafer W1. The wafer W1 may include a plurality of regions 10. Each region 10 may include one complete semiconductor device, for example, a chip. Devices in each region 10 on the wafer W1 may be manufactured by a semiconductor machine implementing a plurality of working procedures (including, but not limited to, deposition, etching, exposure, and development) on a substrate of the wafer. Each working procedure implemented by the semiconductor machine may form a plurality of layers of microstructure on the substrate, to eventually form devices that need to be manufactured.

As manufactured semiconductor devices have different areas, the region 10 may exceed the size limitation of each working procedure implemented by the semiconductor machine. Therefore, in some embodiments, the semiconductor machine may define a plurality of subregions in the region 10. Working procedures can be individually implemented in the subregions in the region 10, to eventually complete the devices that need to be manufactured in the region 10.

In some embodiments, the region 10 may include subregions 10a, 10b, 10c, 10d, 10e, 10f, 10g, 10h, and 10i. In some other embodiments of the present invention, the quantity of subregions can be determined according to an actual requirement. For example, the quantity of subregions may be greater than 9 or less than 9.

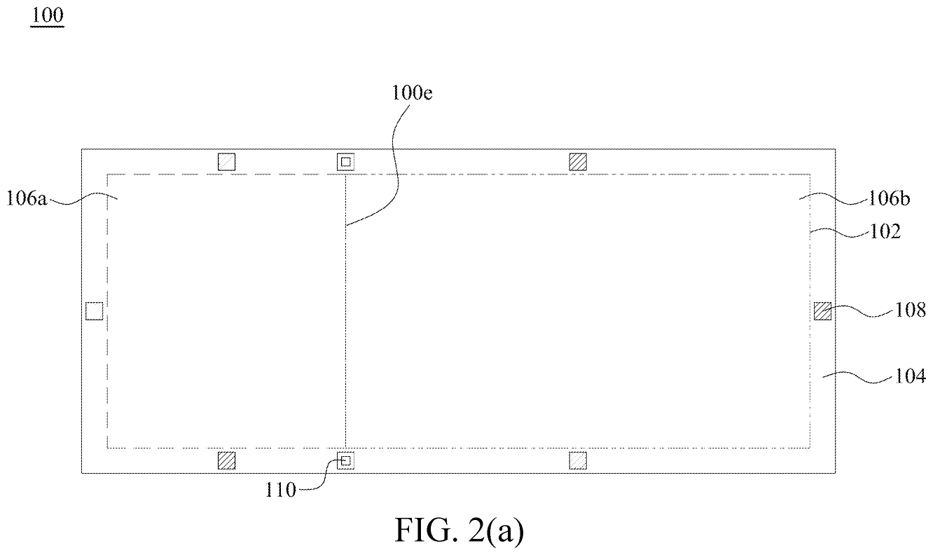

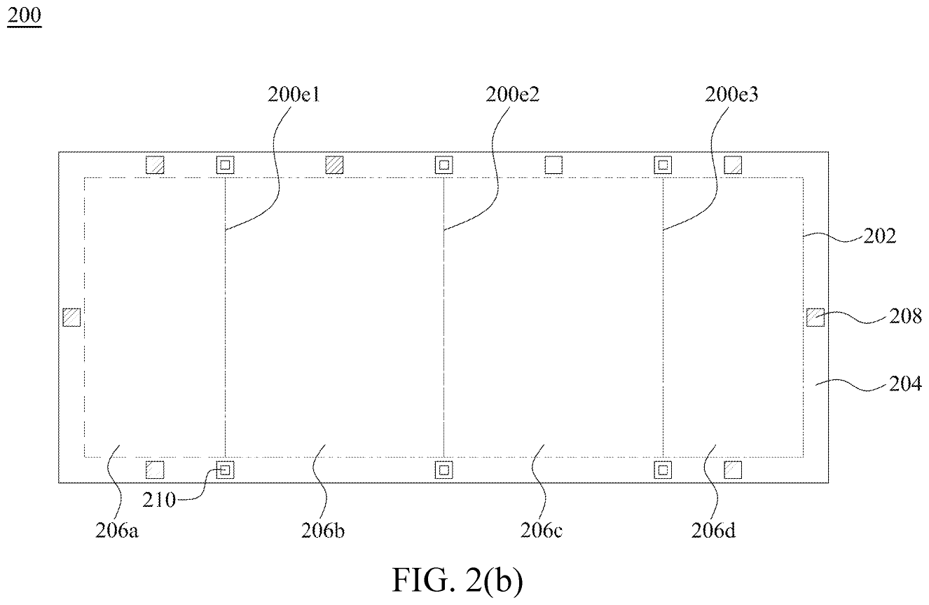

FIG. 2(a) is a schematic diagram of a region on a wafer according to an embodiment of the present invention. As shown in FIG. 2(a), a region 100 is divided into a central region 102 and a circumferential region 104 located outside the central region 102.

The region 100 includes a first subregion 106a and a second subregion 106b. The first subregion 106a and the second subregion 106b are located in the central region 102. The second subregion 106b is adjacent to the first subregion 106a. In FIG. 2(a), the first subregion 106a and the second subregion 106b have different sizes. However, in some other embodiments of the present invention, the first subregion 106a and the second subregion 106b may have the same size.

A plurality of overlay marks 108 may be disposed in the circumferential region 104 of the region 100. The overlay marks 108 may be used for calibrating the position of a specific region on a current layer of the wafer relative to the specific region on one or two previous layers.

In FIG. 2(a), the quantity of the overlay marks 108 is 6. However, in some other embodiments of the present invention, the quantity of the overlay marks 108 can be determined according to an actual requirement. For example, the quantity of the overlay marks 108 may be greater than 6 or less than 6. In addition, in some other embodiments of the present invention, the overlay marks 108 may be disposed at other positions in the circumferential region 104. The overlay marks 108 are not limited to being disposed in the circumferential region 104. In some other embodiments of the present invention, the overlay marks 108 may be disposed at any positions in the region 100.

The size of the first subregion 106a may be less than or equal to an exposure size of the semiconductor machine (for example, an aligner). The size of the second subregion 106b may be less than or equal to the exposure size of the semiconductor machine (for example, the aligner). The size of the region 100 is greater than the exposure size of the semiconductor machine (for example, the aligner). When the size of an electronic component that needs to be manufactured is greater than the exposure size of the semiconductor machine (for example, the aligner), the electronic component may be produced in a stitching manner. That is, different regions of the electronic component may be separately manufactured by using independent exposure procedures, to eventually form the complete electronic component.

When different regions of the electronic component are manufactured by using independent exposure procedures, stitching marks may be disposed on the wafer for calibration between different regions.

For example, a plurality of stitching marks 110 may be disposed in the circumferential region 104 between the first subregion 106a and the second subregion 106b. The plurality of stitching marks 110 may be disposed near an intersection 100e between the first subregion 106a and the second subregion 106b. The plurality of stitching marks 110 may be disposed adjacent to the intersection 100e between the first subregion 106a and the second subregion 106b. The stitching marks may be used for calibrating the position of a current subregion relative to an adjacent subregion. For example, the stitching marks 110 may be used for calibrating the position of the first subregion 106a relative to the second subregion 106b.

In FIG. 2(a), the quantity of the stitching marks 110 is 2. However, in some other embodiments of the present invention, the quantity of the stitching marks 110 can be determined according to an actual requirement. For example, the quantity of the stitching marks 110 may be greater than 2 or less than 2. In addition, in FIG. 2(a), the stitching marks 110 are disposed in the circumferential region 104 between the first subregion 106a and the second subregion 106b. However, in some other embodiments of the present invention, the stitching marks 110 may be disposed in the central region 102 between the first subregion 106a and the second subregion 106b. In some embodiments, the stitching marks 110 may also be disposed in the central region 102 along the intersection 100e.

FIG. 2(b) is a schematic diagram of a region on a wafer according to another embodiment of the present invention. As shown in FIG. 2(b), a region 200 is divided into a central region 202 and a circumferential region 204 located outside the central region 202.

The region 200 includes a first subregion 206a, a second subregion 206b, a third subregion 206c, and a fourth subregion 206d. The first subregion 206a, the second subregion 206b, the third subregion 206c, and the fourth subregion 206d are located in the central region 202. The second subregion 206b is located between the first subregion 206a and the third subregion 206c, and the third subregion 206c is located between the second subregion 206b and the fourth subregion 206d.

A plurality of overlay marks 208 are disposed in the circumferential region 204 of the region 200. The overlay marks 208 may be used for calibrating the position of a specific region on a current layer of the wafer relative to the specific region on one or two previous layers. In FIG. 2(b), the quantity of the overlay marks 208 is 8. However, in some other embodiments of the present invention, the quantity of the overlay marks 208 can be determined according to an actual requirement. For example, the quantity of the overlay marks 208 may be greater than 8 or less than 8. In addition, in some other embodiments of the present invention, the overlay marks 208 may be disposed at other positions of the circumferential region 204. The overlay marks 208 are not limited to be disposed in the circumferential region 204. In some other embodiments of the present invention, the overlay marks 208 can be disposed at any positions in the region 200.

A plurality of stitching marks 210 may be separately disposed in the circumferential region 204 between the first subregion 206a and the second subregion 206b. A plurality of stitching marks 210 may be separately disposed in the circumferential region 204 between the second subregion 206b and the third subregion 206c. A plurality of stitching marks 210 may be separately disposed in the circumferential region 204 between the third subregion 206c and the fourth subregion 206d.

The stitching marks 210 may be disposed near an intersection 200e1 between the first subregion 206a and the second subregion 206b. The stitching marks 210 may be disposed adjacent to the intersection 200e1 between the first subregion 206a and the second subregion 206b. The stitching marks 210 may be disposed near an intersection 200e2 between the second subregion 206b and the third subregion 206c. The stitching marks 210 may be disposed adjacent to the intersection 200e2 between the second subregion 206b and the third subregion 206c. The stitching marks 210 may be disposed near an intersection 200e3 between the third subregion 206c and the fourth subregion 206d. The stitching marks 210 may be disposed adjacent to the intersection 200e3 between the third subregion 206c and the fourth subregion 206d.

The stitching marks may be used for calibrating the position of a current subregion relative to an adjacent subregion. For example, the stitching marks 210 may be used for calibrating the position of the first subregion 206a relative to the second subregion 206b. The stitching marks 210 may be used for calibrating the position of the second subregion 206b relative to the third subregion 206c. The stitching marks 210 may be used for calibrating the position of the third subregion 206c relative to the fourth subregion 206d.

In FIG. 2(b), the quantity of the stitching marks 210 is 6. However, in some other embodiments of the present invention, the quantity of the stitching marks 210 can be determined according to an actual requirement. For example, the quantity of the stitching marks 210 may be greater than 6 or less than 6. In addition, the stitching marks 210 may be disposed at other positions between the first subregion 206a and the second subregion 206b. The stitching marks 210 may be disposed at other positions between the second subregion 206b and the third subregion 206c. The stitching marks 210 may be disposed at other positions between the third subregion 206c and the fourth subregion 206d. In some embodiments, the stitching marks 210 may also be disposed in the central region 202 along the intersection 200e1, 200e2 or 200e3.

It should be understood that in some embodiments of the present invention, the region 100 or the region 200 may include another quantity of subregions, for example, more than three or five subregions. In a specific embodiment of the present invention, the region 100 or the region 200 may be the region 10 shown in FIG. 1. A plurality of overlay marks may be disposed in a circumferential region of the region 100 or the region 200. The plurality of stitching marks may be disposed in circumferential regions between the subregions.

In an existing method for manufacturing an integrated circuit, stitching offsets and overlay offsets are considered as two different types of offsets. Therefore, during calibration, only stitching offsets are independently calibrated, or only overlay offsets are independently calibrated. For example, the semiconductor machine (for example, the aligner) may compute offsets on stitching marks to obtain a parameter set for calibrating stitching offsets. The parameter set obtained can only be used for calibrating stitching offsets. If the parameter set obtained is used for calibrating overlay offsets, an acceptable result cannot be expected. In fact, in the existing manufacturing method, if overlay offsets are calibrated according to the parameter set for calibrating stitching offsets, it is very difficult to meet manufacturing specifications of wafers. Similarly, in the existing manufacturing method, if stitching offsets are calibrated according to the parameter set used for calibrating overlay offsets, it is also very difficult to meet manufacturing specifications of wafers.

The present invention proposes a calibration method that considers both overlay offsets and stitching offsets, and the obtained parameter set can be executed by the semiconductor machine (for example, the aligner) to calibrate both overlay offsets and stitching offsets during the manufacturing of wafers. The calibration method proposed in the present invention may be performed based on the following equation:

L²=αΣᵢ₌₁ⁿ(OVLᵢ−OVL_{M}_{ᵢ})²+βΣⱼ₌₁^{m}(stitchⱼ−Stitch_{M}_{ⱼ})² (Equation 1)

In Equation 1, L² represents a loss value. Equation 1 may also be referred to as a loss function. OVLᵢ represents compensation data associated with an overlay mark on a wafer, OVL_{M}_{ᵢ} represents measurement data associated with an overlay mark on the wafer, Stitchⱼ represents compensation data associated with stitching marks on the wafer, and Stitch_{M}_{ⱼ} represents measurement data associated with a stitching mark on the wafer. α and β respectively represent weight values. The parameter “n” is a positive integer, representing the quantity of overlay marks on the wafer. The parameter “m” is a positive integer, representing the quantity of stitching marks on the wafer.

OVL_{M}_{ᵢ} can be a vector including a magnitude and a direction. OVL_{M}_{ᵢ} may represent an offset obtained through measurement on each overlay mark. Stitch_{M}_{ⱼ} can be a vector including a magnitude and a direction. Stitch_{M}_{ⱼ} may represent an offset obtained through measurement on each stitching mark.

Compensation data OVLᵢ for each overlay mark may be obtained based on the following equation:

OVLᵢ=OVL_locᵢ×t (Equation 2).

In Equation 2, OVL_locᵢ is a coordinate vector of each overlay mark. The coordinate vectors of all the overlay marks on the wafer may form a coordinate matrix. t is a group of parameters or may be referred to as a parameter set. After the computation of OVL_locᵢ and t, the compensation data associated with each overlay mark may be obtained. The compensation data may be a vector including a magnitude and a direction.

Compensation data Stitchⱼ for each stitching mark can be obtained based on the following equation:

Stitchⱼ=Stitch_locⱼ×t (Equation 3).

In Equation 3, Stitch_locⱼ is a coordinate vector of each stitching mark. The coordinate vectors of all the stitching marks on the wafer may form one coordinate matrix. t in Equation 2 and t in Equation 3 are the same group of parameters, and can be referred to as a parameter set. After the computation of Stitch_locⱼ and t, the compensation data associated with each stitching mark can be obtained. The compensation data may be a vector including a magnitude and a direction.

Based on Equation 1, Equation 2, and Equation 3, a parameter set t that enables a loss value L² to meet a preset condition may be computed and found. The parameter set t may be read by the semiconductor machine (for example, the aligner) to calibrate for overlay offsets and stitching offsets during the manufacturing of the wafer.

In some embodiments, a target loss value L_{target} and a loss threshold L_{threshold} may be set to compute the parameter set t. For example, the obtained parameter set t can meet the following condition:

|L_{target}²−L²|≤L_{threshold} (Equation 4).

In some embodiments, the computed parameter set t may be expected to generate the smallest loss value L². In some embodiments, the loss threshold L_{threshold} can be 0.

The weight values α and β may be set according to different manufacturing requirements of wafers. In some embodiments, the weight values α and β may be separately selected according to control specifications associated with wafer manufacturing. In some embodiments, Equation 1 may be rewritten into the following equation according to the selected weight values α and β:

$${L}^{2} = \frac{1}{{S}_{ovl}^{2}} {\sum }_{i = 1}^{n} {( {OVL}_{i} - {OVL}_{{M}_{i}} )}^{2} + \frac{1}{{S}_{stitch}^{2}} {\sum }_{j = 1}^{m} {( {Stitch}_{j} - {Stitch}_{{M}_{j}} )}^{2} . \qquad ( Equation 5 )$$

In Equation 5, Sᵥₒₗ is a specification parameter associated with overlay offsets on the wafer, and S_{stitch} is a specification parameter associated with stitching offsets on the wafer.

In some embodiments, the weight values α and β may further be adjusted according to the quantity of overlay marks and the quantity of stitching marks. In some embodiments, Equation 5 may be rewritten into the following equation according to the quantity of overlay marks and the quantity of stitching marks:

$${L}^{2} = \frac{1}{n * {S}_{ovl}^{2}} {\sum }_{i = 1}^{n} {( {OVL}_{i} - {OVL}_{{M}_{i}} )}^{2} + \frac{1}{m * {S}_{stitch}^{2}} {\sum }_{j = 1}^{m} {( {Stitch}_{j} - {Stitch}_{{M}_{j}} )}^{2} . \qquad ( Equation 6 )$$

In some embodiments, the weight values α and β may further be adjusted according to specification parameters in different directions (for example, the X direction and the Y direction). In some embodiments, after control parameters in different directions are considered, Equation 1 may be rewritten as:

$${L}^{2} = \frac{1}{{S}_{ovlX}^{2}} {\sum }_{i = 1}^{n} {( {OVLX}_{i} - {OVLX}_{{M}_{i}} )}^{2} + \frac{1}{{S}_{stitchX}^{2}} {\sum }_{j = 1}^{m} {( {StitchX}_{j} - {StitchX}_{{M}_{j}} )}^{2} + \frac{1}{{S}_{ovlY}^{2}} {\sum }_{i = 1}^{n} {( {OVLY}_{i} - {OVLY}_{{M}_{i}} )}^{2} + \frac{1}{{S}_{stitchY}^{2}} {\sum }_{j = 1}^{m} {( {StitchY}_{j} - {StitchY}_{{M}_{j}} )}^{2} . \qquad ( Equation 7 )$$

In Equation 7, OVLXᵢ is compensation data (a vector) associated with an overlay mark in the X direction, OVLX_{M}_{ᵢ} is measurement data (a vector) associated with an overlay mark in the X direction, OVLYᵢ is compensation data (a vector) associated with an overlay mark in the Y direction, and OVLY_{M}_{ᵢ} is measurement data (a vector) associated with an overlay mark in the Y direction.

StitchXⱼ is compensation data (a vector) associated with a stitching mark in the X direction, StitchX_{M}_{ⱼ} is measurement data (a vector) associated with a stitching mark in the X direction, StitchYⱼ is compensation data (a vector) associated with the stitching mark in the Y direction, and StitchY_{M}_{ⱼ} is measurement data (a vector) associated with a stitching mark in the Y direction.

S_{volX} is a specification parameter associated with overlay offsets in the X direction, S_{volY} is a specification parameter associated with overlay offsets in the Y direction, S_{stitchX} is a specification parameter associated with stitching offsets in the X direction, and S_{stitchY} is a specification parameter associated with stitching offsets in the Y direction.

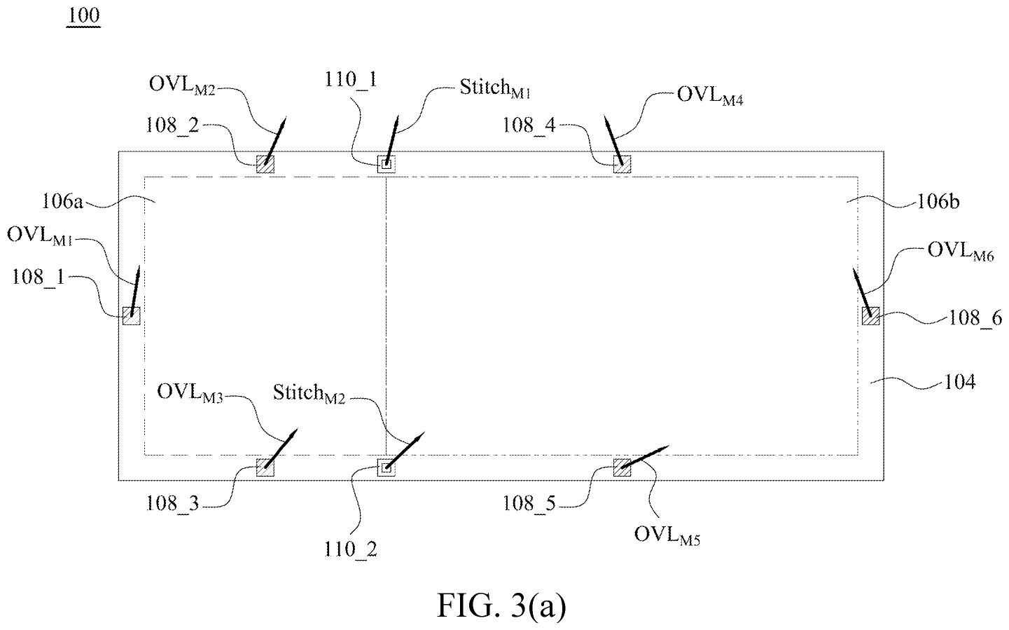

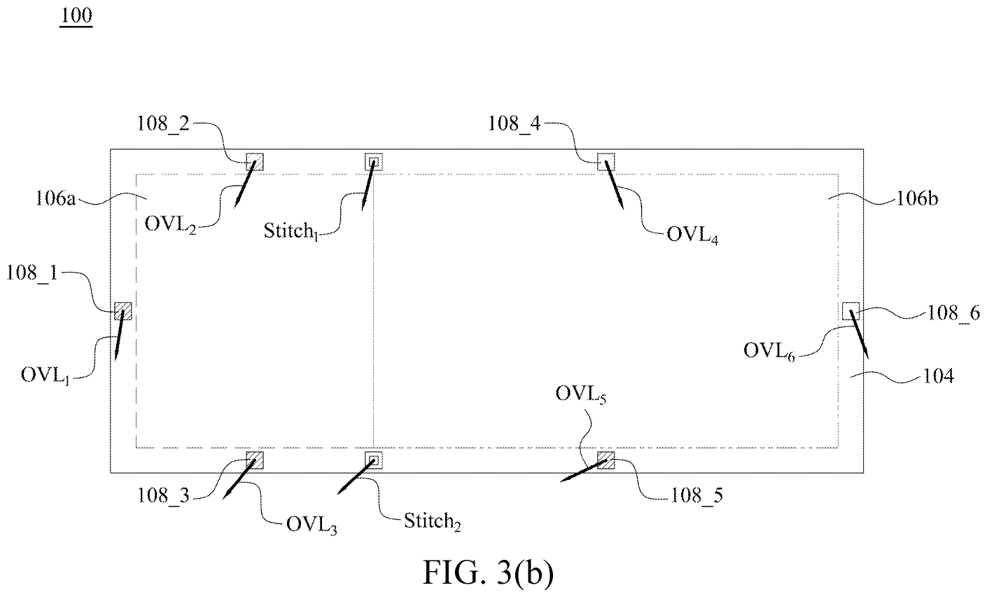

FIG. 3(a) is a schematic diagram of measurement data according to an embodiment of the present invention.

FIG. 3(a) is a schematic diagram of measurement data associated with the region 100 on the wafer. The measurement data represents a magnitude and a direction that needs to be calibrated/compensated for in a wafer manufacturing process. As shown in FIG. 3(a), the overlay marks 108_1, 108_2, 108_3, 108_4, 108_5, and 108_6 are disposed in the circumferential region 104 of the region 100. Stitching marks 110_1 and 110_2 are disposed at an intersection between the first subregion 106a and the second subregion 106b.

Measurement data associated with an overlay mark 108_1 is represented by a vector OVL_{M}_{₁}. Measurement data associated with an overlay mark 108_2 is represented by a vector OVL_{M}_{₂}. Measurement data associated with an overlay mark 108_3 is represented by a vector OVL_{M}_{₃}. Measurement data associated with an overlay mark 108_4 is represented by a vector OVL_{M}_{₄}. Measurement data associated with an overlay mark 108_5 is represented by a vector OVL_{M}_{₅} Measurement data associated with an overlay mark 108_6 is represented by a vector OVL_{M}_{₆}.

Measurement data associated with the stitching mark 110_1 is represented by a vector Stitch_{M}_{₁}. Measurement data associated with the stitching mark 110_2 is represented by a vector Stitch_{M}_{₂}.

In some embodiments, the vector OVL_{M}_{₁}, the vector OVL_{M}_{₂}, the vector OVL_{M}_{₃}, the vector OVL_{M}_{₄}, the vector OVL_{M}_{₅}, and the vector OVL_{M}_{₆} may include different directions and magnitudes. In some embodiments, the vector OVL_{M}_{₁}, the vector OVL_{M}_{₂}, the vector OVL_{M}_{₃}, the vector OVL_{M}_{₄}, the vector OVL_{M}_{₅}, and the vector OVL_{M}_{₆} may include the same direction and magnitude. In some embodiments, the vector Stitch_{M}_{₁} and the vector Stitch_{M}_{₂} may include different directions and magnitudes. In some embodiments, the vector Stitch_{M}_{₁} and the vector Stitch_{M}_{₂} may include the same direction and magnitude.

It needs to be noted that the quantity and positions of the overlay marks and stitching marks shown in FIG. 3(a) are only exemplary, and the quantity and positions of the overlay marks and stitching marks can be determined according to actual requirements in different wafer manufacturing processes. In addition, the magnitudes and directions of vectors shown in FIG. 3(a) are only exemplary and may be different according to actual conditions in different wafer manufacturing processes.

FIG. 3(b) is a schematic diagram of compensation data according to an embodiment of the present invention. FIG. 3(b) is a schematic diagram of compensation data associated with the region 100 on the wafer.

Compensation data associated with the overlay mark 108_1 is represented by a vector OVL₁. Compensation data associated with the overlay mark 108_2 is represented by a vector OVL₂. Compensation data associated with the overlay mark 108_3 is represented by a vector OVL₃. Compensation data associated with the overlay mark 108_4 is represented by a vector OVL₄. Compensation data associated with the overlay mark 108_5 is represented by a vector OVL₅. Compensation data associated with the overlay mark 108_6 is represented by a vector OVL₆.

Compensation data associated with the stitching mark 110_1 is represented by a vector Stitch₁. Compensation data associated with the stitching mark 110_2 is represented by a vector Stitch₂.

The vector OVL₁, the vector OVL₂, the vector OVL₃, the vector OVL₄, the vector OVL₅, and the vector OVL₆ shown in FIG. 3(b) may be respectively used for compensating for the vector OVL_{M}_{₁}, the vector OVL_{M}_{₂}, the vector OVL_{M}_{₃}, the vector OVL_{M}_{₄}, the vector OVL_{M}_{₅}, and the vector OVL_{M}_{₆} shown in FIG. 3(a). The vector Stitch₁ and the vector Stitch₂ shown in FIG. 3(b) may be respectively used for compensating for the vector Stitch_{M}_{₁} and the vector Stitch_{M}_{₂} shown in FIG. 3(a).

In some embodiments, the vector OVL₁, the vector OVL₂, the vector OVL₃, the vector OVL₄, the vector OVL₅, and the vector OVL₆ may include different directions and magnitudes. In some embodiments, the vector OVL₁, the vector OVL₂, the vector OVL₃, the vector OVL₄, the vector OVL₅, and the vector OVL₆ may include the same direction and magnitude. In some embodiments, the vector Stitch₁ and the vector Stitch₂ may include different directions and magnitudes. In some embodiments, the vector Stitch₁ and the vector Stitch₂ may include the same direction and magnitude.

The magnitudes and directions of the vectors shown in FIG. 3(b) are only exemplary and may be different according to actual conditions in different wafer manufacturing processes.

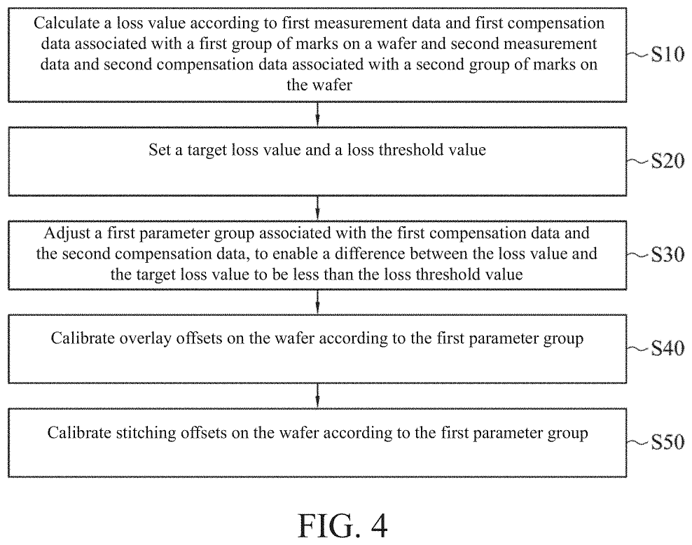

FIG. 4 is a flowchart of a method for manufacturing an integrated circuit according to an embodiment of the present invention. The flowchart of FIG. 4 may be used for manufacturing the wafer W1 shown in FIG. 1. The flowchart of FIG. 4 may be used for manufacturing an integrated circuit in the region 100 shown in FIG. 2(a). The flowchart of FIG. 3 may be used for manufacturing an integrated circuit in the region 200 shown in FIG. 2(b). In some embodiments, a procedure of the method in FIG. 4 may be operated by a semiconductor manufacturing machine. In some embodiments, a procedure of the method in FIG. 4 may be operated by the aligner.

As shown in FIG. 4, in the operation S10, a loss value is calculated according to first measurement data and first compensation data associated with a first group of marks on a wafer and second measurement data and second compensation data associated with a second group of marks on the wafer.

In some embodiments, in the operation S10, a loss value L² may be calculated according to the vector OVL_{M}_{₁}, the vector OVL_{M}_{₂}, the vector OVL_{M}_{₃}, the vector OVL_{M}_{₄}, the vector OVL_{M}_{₅}, and the vector OVL_{M}_{₆} that are respectively correlated to the overlay marks 108_1, 108_2, 108_3, 108_4, 108_5, and 108_6 and the vector Stitch_{M}_{₁} and the vector Stitch_{M}_{₂} that are respectively correlated to the stitching marks 110_1 and 110_2. The loss value L² in the operation S10 may be calculated according to Equation 1 to Equation 7.

In the operation S20, a target loss value and a loss threshold are set. In some embodiments, a target loss value L_{target} and a loss threshold L_{threshold} may be set.

In the operation S30, a first parameter set associated with the first compensation data and the second compensation data is adjusted, to enable a difference between the loss value and the target loss value to be less than the loss threshold. In some embodiments, a parameter set t is adjusted to enable a difference between the loss value L² and the target loss value L_{target} to be less than the loss threshold L_{threshold} (referring to Equation 4). In addition, according to Equation 2, the parameter set t is correlated to compensation data OVLᵢ of an overlay mark. According to Equation 3, the parameter set t is correlated to compensation data Stitchⱼ of a stitching mark.

In the operation S40, overlay offsets on the wafer are calibrated according to the first parameter set. In some embodiments, the overlay offsets on the wafer are calibrated according to the parameter set t obtained in the operation S30.

In the operation S50, stitching offsets on the wafer are calibrated according to the first parameter set. In some embodiments, stitching offsets on the wafer are calibrated according to the parameter set t obtained in the operation S30. It needs to be noted that, although an order of the operation S40 and the operation S50 is shown in FIG. 4, in some embodiments, the operation S40 and the operation S50 may be performed simultaneously, and in some embodiments, the operation S50 may be performed before the operation S40.

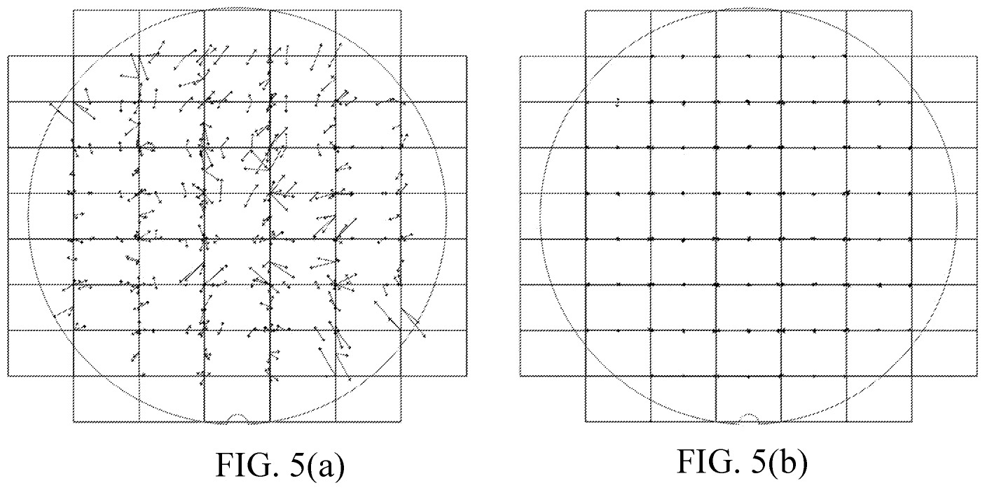

FIG. 5(a) is a vector diagram of overlay offsets after the method shown in FIG. 4 is performed. Specifically, FIG. 5(a) is a diagram of the remaining offset vectors that require compensation after the method shown in FIG. 4 is used to perform calibration. As can be known from FIG. 5(a), offset vector values of the overlay marks are already very small. That is, after compensation, offset values between overlay marks on a current layer of the wafer and overlay marks on one or two previous layers are already greatly reduced, thereby enormously reducing overlay offsets on the wafer.

FIG. 5(b) is a vector diagram of stitching offsets obtained after the method shown in FIG. 4 is performed. As can be learned from FIG. 5(b), after compensation, the values of stitching offsets between regions on the wafer are very small and are nearly omittable. That is, after compensation, the stitching offsets between the regions are also enormously reduced.

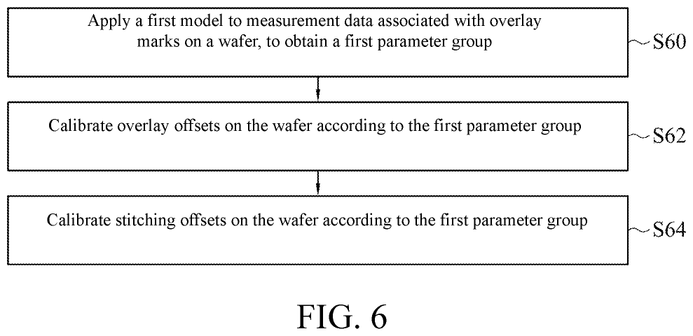

FIG. 6 is a flowchart of a method for manufacturing an integrated circuit according to a comparative embodiment of the present invention.

In the operation S60, a first model is applied to measurement data associated with overlay marks on a wafer, to obtain a first parameter set. For example, a conventional overlay model (for example, a wafer level model or a region level model) is applied to measurement data associated with all overlay marks on the wafer, to obtain a parameter set Ds1.

In the operation S62, the overlay offsets on the wafer are calibrated according to the first parameter set. For example, the overlay offsets on the wafer are compensated for according to the parameter set Ds1. Specifically, the semiconductor machine (for example, the aligner) may compensate for overlay offsets between a current layer of the wafer and one or two previous layers according to the parameter set Ds1.

In the operation S64, stitching offsets on the wafer are calibrated according to the first parameter set. For example, compensation is performed on the stitching offsets on the wafer according to the parameter set Ds1. It needs to be noted that, because the parameter set Ds1 is obtained according to a conventional overlay model, the operation S64 of compensating for the stitching offsets according to the parameter set Ds1 cannot achieve an adequate calibration effect.

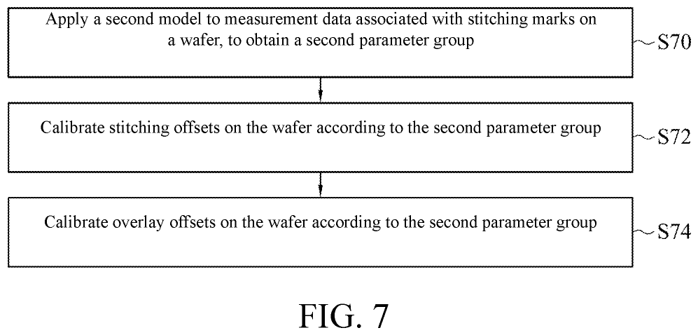

FIG. 7 is a flowchart of a method for manufacturing an integrated circuit according to a comparative embodiment of the present invention.

In the operation S70, a second model is applied to measurement data associated with stitching marks on a wafer, to obtain a second parameter set.

For example, a conventional stitching model (for example, a wafer level model or a region level model) is applied to measurement data associated with all stitching marks on the wafer, to obtain a parameter set Ds2.

In the operation S72, stitching offsets on the wafer are calibrated according to the second parameter set. For example, the stitching offsets on the wafer are compensated for according to the parameter set Ds2. Specifically, the semiconductor machine (for example, the aligner) may compensate for stitching offsets between regions on the wafer according to the parameter set Ds2.

In the operation S74, overlay offsets on the wafer are calibrated according to the second parameter set. For example, the overlay offsets on the wafer are compensated for according to the parameter set Ds2. It needs to be noted that, because the parameter set Ds2 is obtained according to the conventional stitching model, and the operation S74 of compensating for the overlay offsets according to the parameter set Ds2 cannot achieve an adequate calibration effect.

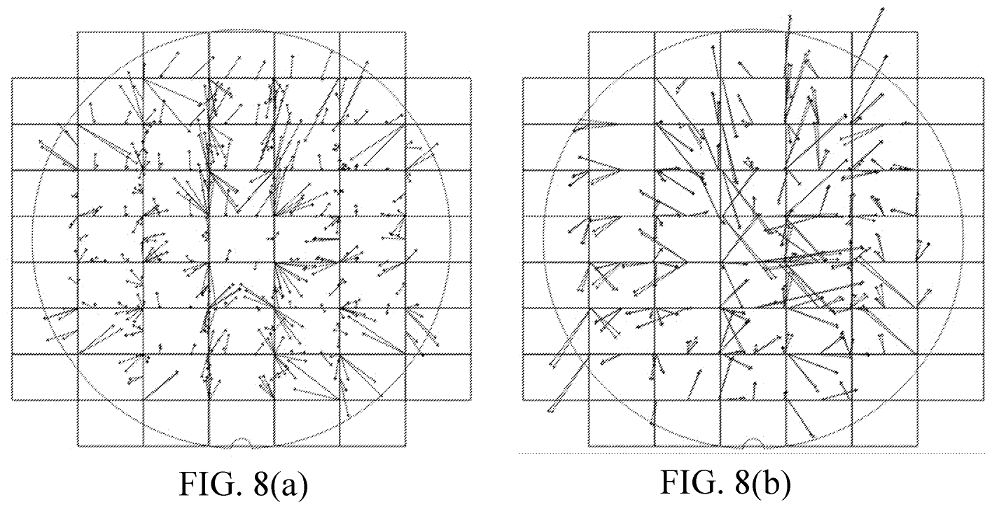

FIG. 8(a) is a vector diagram of overlay offsets after the method shown in FIG. 6 is performed. Specifically, FIG. 8(a) is a schematic diagram of the remaining offset vectors that require compensation after the method shown in FIG. 6 is used to compensate for overlay offsets on the wafer (that is, the operation S62). Compared with the diagram of offset vectors FIG. 5(a), offset vector values shown in FIG. 8(a) are still relatively large.

FIG. 8(b) is a vector diagram of stitching offsets obtained after the method shown in FIG. 6 is performed. Specifically, FIG. 8(b) is a schematic diagram of the remaining offset vectors that require compensation after the method shown in FIG. 6 is performed to compensate for stitching offsets on the wafer (that is, the operation S64). Compared with a diagram of offset vectors shown in FIG. 5(b), the offset vector values shown in FIG. 8(b) are still relatively large.

Similarly, after the method shown in FIG. 7 is performed, the remaining offset vectors that require compensation in the vector diagram of overlay offsets will be greater than offset vector values shown in FIG. 5(a). Similarly, after the method shown in FIG. 7 is performed, the remaining offset vectors that require compensation in the vector diagram of stitching offsets will be greater than offset vector values shown in FIG. 5(b).

TABLE 1

| | | Remaining offset | Remaining offset | |
|---|---|---|---|---|
| | | value obtained after | value obtained after | |
| | | the method in FIG. 6 | the method in FIG. 4 | |
| | X/Y (horizontal | is used to perform | is used to perform | |
| | direction/vertical | compensation (unit: | compensation (unit: | Reduction |
| | direction) | nanometer) | nanometer) | rate |
| Value of an | X | 23.6 | 11.8 | 50% |
| overlay offset | Y | 28.2 | 12.1 | 57% |
| Value of a | X | 42.8 | 2.0 | 95% |
| stitching offset | Y | 41.8 | 1.9 | 95% |

As can be known from Table 1, compared with FIG. 8(a), the values of the remaining overlay offsets obtained after the compensation in FIG. 5(a) are reduced by 50% and 57% (50% in the horizontal direction and 57% in the vertical direction). That is, compared with the method shown in FIG. 6, the method shown in FIG. 4 significantly reduces overlay offsets on the wafer.

In addition, compared with FIG. 8(b), the values of the remaining stitching offsets obtained after the compensation in FIG. 5(b) are both reduced by 95% (95% in the horizontal direction, and also 95% in the vertical direction). That is, compared with the method shown in FIG. 6, the method shown in FIG. 4 significantly reduces stitching offsets on the wafer.

Therefore, the efficiency of compensating for overlay offsets and stitching offsets of the method shown in FIG. 4 is much higher than that of the method shown in FIG. 6. Similarly, the efficiency of compensating for overlay offsets and stitching offsets of the method shown in FIG. 4 is also much higher than that of the method shown in FIG. 7.

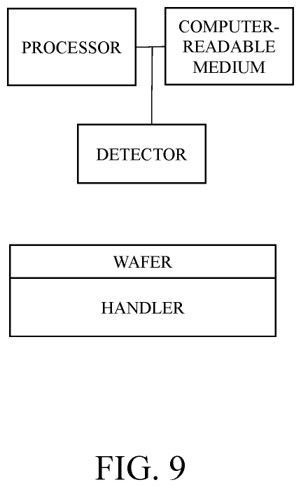

In addition, some other embodiments of the present invention further provide a system for manufacturing an integrated circuit, such as that illustrated in FIG. 9. The system includes a processor, a nonvolatile computer-readable medium storing computer executable instructions, and a handler. The nonvolatile computer-readable medium storing computer executable instructions may be coupled to the processor. The handler may be configured to support a wafer. The processor may execute the computer executable instructions to implement the method for manufacturing an integrated circuit shown in FIG. 4, FIG. 6, and FIG. 7 on the wafer. In the present invention, stitch compensation and overlay compensation are both considered to propose a method for obtaining calibration. With the method for manufacturing an integrated circuit proposed in the present invention, both overlay offsets and stitching offsets can be significantly reduced.

The processor may be any suitable processor known in the art, such as a parallel processor, and may be part of a personal computer system, image computer, mainframe computer system, workstation, network appliance, internet appliance, or other device. In some embodiments, various steps, functions, and/or operations of the system and the sub-systems therein and the methods disclosed herein are carried out by one or more of the following: electronic circuits, logic gates, multiplexers, programmable logic devices, ASICs, analog or digital controls/switches, microcontrollers, or computing systems. For instance, the various steps described throughout the present disclosure may be carried out by a single processor (or computer system) or, alternatively, multiple process (or multiple computer systems). Therefore, the above description should not be interpreted as a limitation on the present disclosure but merely an illustration.

The system may include a detector, which can use an optical beam or electron beam to image or otherwise measure features on a wafer.

It should be noted that the wording “an embodiment of the present invention” or a similar term throughout this specification, with reference to its purpose, is intended to point out that a specific feature, structure, or property described together with another embodiment is included in at least one embodiment and is not necessarily presented in all embodiments. Therefore, when the wording “an embodiment of the present invention” or a similar term correspondingly appears throughout this specification, it does not necessarily represent a same embodiment. In addition, the specific features, structures or characteristics in any specific embodiments may be combined with one or more other embodiments in any suitable manner.

Technical content and technical features of the present invention are disclosed above. However, a person skilled in the art may still make replacements and modifications based on the teachings and the disclosure of the present invention without departing from the spirit of the present invention. Therefore, the protection scope of the present invention should not be limited to the content disclosed in the embodiments, and should include various replacements and modifications without departing from the present invention, and is covered by the claims of this patent.

We claim:

1. A method for manufacturing an integrated circuit, comprising:
calculating, using a processor, a loss value according to first measurement data and first compensation data associated with a first group of marks on a wafer and second measurement data and second compensation data associated with a second group of marks on the wafer; and
adjusting, using the processor, a first parameter set associated with the first compensation data and the second compensation data such that a difference between the loss value and a target loss value is less than a loss threshold.

2. The method for manufacturing an integrated circuit according to claim 1, further comprising:
calibrating overlay offsets on the wafer according to the first parameter set; and
calibrating stitching offsets on the wafer according to the first parameter set.

3. The method for manufacturing an integrated circuit according to claim 1, wherein the first group of marks are disposed in the circumference of a first region and a second region on the wafer, and the second group of marks are disposed near an intersection between the first region and the second region.

4. The method for manufacturing an integrated circuit according to claim 1, wherein the loss value is further calculated according to a first weight value associated with the first group of marks and a second weight value associated with the second group of marks.

5. The method for manufacturing an integrated circuit according to claim 4, wherein the first weight value is associated with the quantity of the first group of marks, and the second weight value is associated with the quantity of the second group of marks.

6. The method for manufacturing an integrated circuit according to claim 4, wherein the first weight value is inversely proportional to the quantity of the first group of marks, and the second weight value is inversely proportional to the quantity of the second group of marks.

7. The method for manufacturing an integrated circuit according to claim 1, wherein the first compensation data is obtained according to the first parameter set and a first coordinate matrix associated with the first group of marks.

8. The method for manufacturing an integrated circuit according to claim 1, wherein the second compensation data is obtained according to the first parameter set and a second coordinate matrix associated with the second group of marks.

9. The method for manufacturing an integrated circuit according to claim 1, wherein
the first compensation data comprises a first group of components associated with the first group of marks in a first direction and a second group of components associated with the first group of marks in a second direction.

10. The method for manufacturing an integrated circuit according to claim 1, wherein
the second compensation data comprises a first group of components associated with the second group of marks in a first direction and a second group of components associated with the second group of marks in a second direction.

11. The method for manufacturing an integrated circuit according to claim 1, wherein
the first measurement data comprises a first group of components associated with the first group of marks in a first direction and a second group of components associated with the first group of marks in a second direction.

12. The method for manufacturing an integrated circuit according to claim 1, wherein
the second measurement data comprises a first group of components associated with the second group of marks in a first direction and a second group of components associated with the second group of marks in a second direction.

13. A method for manufacturing an integrated circuit, comprising:
calculating a loss value for a wafer using a processor according to the following equation:
$${L}^{2} = α {\sum }_{i = 1}^{n} {( {OVL}_{i} - {OVL}_{{M}_{i}} )}^{2} + β {\sum }_{j = 1}^{m} {( {Stitch}_{j} - {Stitch}_{{M}_{j}} )}^{2} ,$$
wherein
L² is the loss value;
OVLᵢ is first compensation data associated with a first group of marks on the wafer;
OVL_{M}_{ᵢ} is first measurement data associated with the first group of marks;
Stitchⱼ is second compensation data associated with a second group of marks on the wafer;
Stitch_{M}_{ⱼ} is second measurement data associated with the second group of marks;
α is a first weight value; and
β is a second weight value.

14. The method for manufacturing an integrated circuit according to claim 13, further comprising adjusting a first parameter set associated with the first compensation data and the second compensation data such that a difference between the loss value and a target loss value is less than a loss threshold.

15. The method for manufacturing an integrated circuit according to claim 14, wherein the first compensation data is obtained according to the first parameter set and a first coordinate matrix associated with the first group of marks, and the second compensation data is obtained according to the first parameter set and a second coordinate matrix associated with the second group of marks.

16. The method for manufacturing an integrated circuit according to claim 14, further comprising:
calibrating overlay offsets on the wafer according to the first parameter set; and
calibrating stitching offsets on the wafer according to the first parameter set.

17. The method for manufacturing an integrated circuit according to claim 13, wherein
the first weight value is
$$\frac{1}{{S}_{ovl}^{2}} ;$$
the second weight value is
$$\frac{1}{{S}_{stitch}^{2} ;}$$
Sᵥₒₗ is a specification parameter associated with overlay offsets on the wafer; and
S_{stitch} is a specification parameter associated with stitching offsets on the wafer.

18. The method for manufacturing an integrated circuit according to claim 13, wherein
the first weight value is
$$\frac{1}{n * {S}_{ovl}^{2}} ;$$
the second weight value is
$$\frac{1}{m * {S}_{stitch}^{2}} ;$$
Sᵥₒₗ is a specification parameter associated with overlay offsets on the wafer;
S_{stitch} is a specification parameter associated with stitching offsets on the wafer;
n is the quantity of the first group of marks; and
m is the quantity of the second group of marks.

19. The method for manufacturing an integrated circuit according to claim 17, further comprising calculating a loss value using the processor according to the following equation:
$${L}^{2} = \frac{1}{{S}_{ovlX}^{2}} {\sum }_{i = 1}^{n} {( {OVLX}_{i} - {OVLX}_{{M}_{i}} )}^{2} + \frac{1}{{S}_{stitchX}^{2}} {\sum }_{j = 1}^{m} {( {StitchX}_{j} - {StitchX}_{{M}_{j}} )}^{2} + \frac{1}{{S}_{ovlY}^{2}} {\sum }_{i = 1}^{n} {( {OVLY}_{i} - {OVLY}_{{M}_{i}} )}^{2} + \frac{1}{{S}_{stitchY}^{2}} {\sum }_{j = 1}^{m} {( {StitchY}_{j} - {StitchY}_{{M}_{j}} )}^{2} ,$$
wherein
OVLXᵢ is compensation data associated with the first group of marks in a first direction;
OVLX_{M}_{ᵢ} is measurement data associated with the first group of marks in the first direction;
OVLYᵢ is compensation data associated with the first group of marks in a second direction;
OVLY_{M}_{ᵢ} is measurement data associated with the first group of marks in the second direction;
StitchXⱼ is compensation data associated with the second group of marks in the first direction;
StitchX_{M}_{ⱼ} is measurement data associated with in the second group of marks in the first direction;
StitchYⱼ is compensation data associated with the second group of marks in the second direction;
StitchY_{M}_{ⱼ} is measurement data associated with in the second group of marks in the second direction;
S_{volX} is a specification parameter associated with overlay offsets in the first direction on the wafer;
S_{volY} is a specification parameter associated with overlay offsets in the second direction on the wafer;
S_{stitchX} is a specification parameter associated with stitching offsets in the first direction on the wafer; and
S_{stitchY} is a specification parameter associated with stitching offsets in the second direction on the wafer.

20. A system for manufacturing an integrated circuit, comprising:
a processor;
a non-transitory computer-readable medium, storing computer executable instructions, and coupled to the processor; and
a handler, configured to support a wafer,
wherein the processor is capable of executing the computer executable instructions to:
calculate a loss value according to first measurement data and first compensation data associated with a first group of marks on a wafer and second measurement data and second compensation data associated with a second group of marks on the wafer; and
adjust a first parameter set associated with the first compensation data and the second compensation data such that a difference between the loss value and a target loss value is less than a loss threshold.
